(19) United States
(12) Patent Application Publication
(10) Pub. No.: US 2015/0364709 A1
(43) Pub. Date: Dec. 17, 2015

(54) PRIMARY PACKAGING COMPRISING PHOTOVOLTAIC DEVICE

(71) Applicant: EIGHT19 LIMITED, Cambridge, Cambridgeshire (GB)

(72) Inventors: Jurjen Winkel, Cambridge, Cambridgeshire (GB); Michael Niggemann, Cambridge, Cambridgeshire (GB)

(21) Appl. No.: 14/763,186

(22) PCT Filed: Jan. 27, 2014
(86) PCT No.: PCT/GB14/50200

§ 371 Date: Jul. 24, 2015

(30) Foreign Application Priority Data
Jan. 25, 2013 (GB) 1301367.7

(51) Int. Cl. H01L 51/44

(52) U.S. Cl. CPC H01L 51/448

(57) ABSTRACT

Primary packaging (403) is disclosed comprising an encapsulated volume or enclosure (402), and a solar cell (401) having a transparent electrode (406), the solar cell (401) being provided on a surface of the encapsulated volume or enclosure (402) with the transparent electrode (406) facing towards the encapsulated volume or enclosure. The packaging enables the distribution of solar cells, improves the collection of packaging for recycling and/or reduces the carbon footprint of consumer products by utilising packaging which comprises one or more solar cells. The main purpose is for the solar cells to be used in ways other than interacting with the package or the package contents directly.

The present invention relates in general to primary packaging that includes photovoltaic devices for converting solar power into energy in which the converting device is integral or attached to the primary packaging. In particular this invention provides a continued use of the primary packaging which would otherwise be discarded.

Lack of access to electricity and energy poverty is a major concern in many developing countries. There is no electricity grid in many rural communities and despite typically high levels of insulation, photovoltaic systems are not affordable to the local population, as disposable income is typically low and the up-front costs of solar panels is high, and finance is not always available locally. Other potential challenges revolve around theft of high value photovoltaic off-grid systems and a lack of local, field based, maintenance capability. These communities have a need for basic provisions such lighting, phone charging, radio, refrigeration, etc. Lighting is often provided by kerosene burning lamps. Electricity for mobile phone charging is typically provided by diesel generators in larger villages, towns or cities.

Solar power has enabled significant progress in the provision of electricity for remote areas or communities not served by national grid systems. The development of solar lanterns as replacements for kerosene lanterns has started to make inroads, bringing enormous health benefits as well as the environmental advantage of reducing carbon emissions. However, the availability of solar power is hampered by the large cost barrier associated with the purchase and management of a solar energy supply and even solar lanterns are not affordable to many households in, for example, large parts of Africa and Asia.

A further obstacle is the distribution of photovoltaic systems to remote rural areas. Most conventional commercially available solar modules such as wafer based silicon or CdTe thin film modules have a peak power to weight ratio below 10 Wp/Kg. This is mainly due to glass encapsulation and metal framing required to protect the brittle wafers and inorganic thin films. Distributing these types of large, heavy, fragile and expensive solar modules to rural areas with a poor road access is a logistical and costly challenge. Distribution networks have to be built up, which can constitute a significant business challenge (and therefore business risk).

Conventional photovoltaic systems are most often based on silicon wafer technology assembled into PV modules. These solar modules are designed for an operational life time of several tens of years. Often a number of modules are connected together in parallel and/or in series to supply more power and a suitable output voltage. Besides the intrinsic stability of the materials, the long operational life is achieved by encapsulation using glass plates and highly durable back sheets. Recycling can be carried out by separating the materials for further use, but requires intensive processing. The processes involved are mechanical crushing, chemical dissolving and sorting, all energy consuming activities.

For non-durable consumer goods in developing economies, distribution of the smallest units has proven to be a successful way for companies to gain access to a larger customer base. An example is the use of sachets, which are the smallest affordable unit for many fast moving consumer goods like hygiene, health and nutrition goods in developing markets and have proven to be a very successful vehicle for gaining access to the bottom of the consumer pyramid.

This success poses different challenges, as the waste products produced by the more than 80Bn sachets consumed annually threaten to cause significant environmental problems. Recycling techniques have recently been developed that allow the reclaiming of part of the embedded energy by using waste sachets as fuel. However, the main challenge is the lack of incentive for collection or for further use of the waste products generated once sachet contents have been consumed.

Another example is to be found with consumption of drinks supplied in plastic bottles, which create some 2,680,00 tons of non-biodegradable PET bottles per year, of which less than one third are recovered and recycled.

Similar examples can readily be envisaged in relation to the disposal of paper, cardboard and foil packaging.

Packaging materials constitute a significant level of embedded energy. Whilst simple burning can yield some energy payback, production and transportation will still significantly contribute to carbon emissions.

### Organic Photovoltaic Cells and Modules

A photovoltaic cell contains a photoactive material which absorbs electromagnetic radiation; the absorbed photonic energy is converted into electrical energy via the photovoltaic effect. Solar cells are photovoltaic cells that convert sunlight into electrical energy.

The development of photovoltaic cells, in particular solar cells, has attracted considerable interest in recent years as society searches for cleaner energy generation technologies.

A solar cell has the form of a layered structure comprising a transparent electrode, a photoactive layer and a back electrode.

In operation, electromagnetic radiation from the sun passes through the front electrode into the photoactive layer. Within the photoactive layer, photons are absorbed resulting in the generation of electron-hole pairs. The electron-hole pairs are separated within the photoactive layer, with electrons travelling to one electrode, e.g. the front electrode, and holes travelling to the other electrode, e.g. the back electrode. The extraction of charge carriers from the semiconductor is often facilitated by specifically designed extraction layers. Examples for electron extraction layers are Cr, ZnO, TiOx, etc., for hole extraction layers (MoO3, WOx, PEDOT:PSS, AgO, NiO).

Typically, the back electrode may be reflective. An antireflection coating may be applied to a surface of the transparent front electrode.

A photovoltaic device can be formed a photovoltaic cell and a photovoltaic cell is the smallest functional unit. A plurality of cells may be grouped together to form a module. A solar module is a particular type of module with a photoactive region particularly sensitive to sunlight.

The definition of device, cell and module is applicable to wafer based (e.g.) silicon photovoltaics. Wafers can be interconnected in series to increase the output voltage or in parallel to increase the current by maintaining the voltage. Both types of interconnections schemes can be combined to achieve the appropriate voltage and current. Thin film solar modules are most often not wafer based. The thin films are applied on large areas. The efficient extraction of power from these areas, and the generation of appropriate voltage, is achieved by patterning (typically into stripes) and series interconnection of adjacent stripes. This is termed monolithic series interconnection. In principle the current can also be collected from larger areas by increasing the effective conductivity of the transparent electrode. This can for instance be achieved by applying metal grid fingers. Such a structure could be described as a module as the current is collected from a larger area (effectively a parallel interconnection) or as a large cell.

A solar cell is a particular variant of a photovoltaic cell and interchangeable depending on the light source. Module should be interpreted accordingly.

In the context of the invention disclosed here, primary packaging may be used to provide small photovoltaic units as part of packaging for use in a series of interconnected cells forming a mini-module or a large cell. An electrical load may be connected between the front and back electrodes.

Organic, typically polymeric, photoactive materials are being investigated as an alternative to inorganic materials such as silicon, cadmium telluride and gallium arsenide. Also, organic photoactive materials comprising small molecules deposited by vapour deposition techniques are being investigated, as well as photovoltaic systems which mix organic and inorganic components (such as nanoparticles or nanostructures).

Organic photovoltaic cells and modules promise significant advantages in terms of ease and cost of manufacture. A notable advantage is that organic photovoltaic cells or modules can be manufactured using printing or coating methods as thin films on substrates which may be lightweight and/or flexible, thereby offering easier installation and increased versatility. Alternatively, some types of OPV systems, or individual layers, of organic photovoltaic modules can be deposited by vacuum processes. In contrast to the peak watt to weight ratio below 10 Wp/Kg of most inorganic, glass encapsulated solar modules, a 5% efficient organic photovoltaic module can achieve 100 Wp/Kg or more depending on the type of flexible encapsulation chosen.

### Packaging Materials and Labels

Packaging and labelling covers a wide subset of materials, from rigid glass bottles and tin cans to flexible foil and paper wrappers, but in all instances the intent is to ensure that the product reaches the customer in a useable condition. The packaging will typically also provide a vehicle for branding of the goods, as well as for providing printable space to include information on what the package contains. The packaging forming an enclosure for the packaged goods is called here a primary packaging. This primary packaging can be partially covered by additional packaging material in form of a label.

Flexible packaging materials are thought to be particularly advantageous for use in the present invention as they offer easy printing (branding and information provision) and typically utilise large scale roll to roll production processes and facilities to deliver low cost production of high volume materials. Flexible packaging materials can typically comprise card, cardboard, paper, plasticised paper, plastics and or foils. Printing of product information (here also called a print), logos, images, etc. is done by various methods like screen printing, flexo, ink jet, gravure, off-set, etc.

A subset of flexible packaging materials, which is also suitable for the production of substrates or labels, is based on polymer materials, such as Polyethylene (LDPE, HDPE), Polypropylene, Polyvinyl chloride (PVC), Polyvinylidene chloride (PVDC), polyamides (Nylons), Polyethylene terephthalate (PET), and cellulose/cellulose acetate. Often combinations of materials are used—combined materials can be coextruded or laminated together using suitable adhesive materials. Thin metal layers deposited by vacuum processes (metallisation) can be applied if good barrier properties are required. Lamination processes (hotmelt, epoxy based systems, Uv-curable systems, etc.) can also be used to build up composites of different materials. Further processes established in the fabrication of packaging materials suitable for use as primary packaging are coating, printing (screen, flexo, gravure, ink-jet), slitting and die cutting and the application of adhesives.

### Types, Processes, Materials Required, Etc.

### Barrier Materials

Photovoltaic modules are typically covered with a transparent protective material which has the advantage of making the devices more robust to physical damage, as well as protecting them from the elements. For Si based devices this layer can be a coated or cast layer or an applied barrier material, such as a plastic substrate or a sheet of glass. These plastic substrates are typically applied with an adhesive made of EVA (ethylene-vinyl acetate), although many other materials have been developed over the years as adhesive layer with enhanced light and thermal stability, weather-proofing capability, etc.

For thin film solar cells and modules protective barriers with improved moisture and oxygen transmission characteristics have been developed, as many of the materials that are used to produce the solar devices are susceptible to degradation in the presence of moisture and oxygen. Correspondingly it is typically a requirement to fully encapsulate these devices in such a way as to ensure that no oxygen or moisture ingress occurs, or at the very least occurs at a very significantly reduced rate, through the front, the back or the edges of the PV module. Barrier requirements vary depending on the material sets employed, but as an example for Organic Photovoltaic devices, barrier film properties in the order of 10⁻² g/m²/day WVTR (water vapour transmission rate) or better, as for instance measured using a MOCON test (typically carried out at near 100% humidity at elevated temperatures), are currently required to provide commercially relevant device lifetimes.

One option for oxygen or moisture sensitive devices is to encapsulate devices with glass on the front side as this has extremely good barrier properties, although drawbacks are the inherent mass and/or fragility of cost effective glass materials, especially where it is employed in larger modules.

An alternative option for the transparent side is to use a polymeric film with an integrated barrier. High barrier films are typically produced using successive inorganic/organic stacks, with the number of dyads determining the final barrier properties. Additionally it is an option to include oxygen or moisture absorbing/scrubbing materials in these layers to further improve permeation rates. Examples of these high barrier materials include Barix multilayers and film materials produced by Alcan and 3M amongst others.

Similar materials can be used for the back side encapsulation, although as it is not a requirement for the back side encapsulation to be transparent in many instances. A more typical configuration is to make use of an opaque barrier as these can be manufactured at significantly lower cost for instance by thermal evaporation of a layer of suitably high barrier metal or even use of thin metal sheets with a suitable dielectric adhesive layer. The latter is very similar to the approach taken for certain food grade barriers where for example aluminium metallisation is commonplace.

Oxygen and moisture ingress from the edges can be minimised by use of high barrier adhesives (low WVTR) to attach the two barriers to the PV module. The adhesives could in principle be of any type, but it is important that the correct chemical and mechanical synergies are achieved. The adhesive can be coated, or can be a pressure sensitive adhesive pre applied to the barrier.

A further alternative is to build the device directly onto a barrier material such as the aforementioned glass, plastic or metal based barrier materials, which could be either opaque or transparent depending on device architecture.

The present state of the art photovoltaic systems are too expensive to distribute and purchase for the vast majority of the indigenous population in developing countries, whilst at the same time current high volume consumer goods, whilst having good market penetration, cause significant environmental damage through direct pollution (waste), as well as contributing significantly CO² to the atmosphere as a result of manufacture and distribution.

The invention aims to improve affordability, enable the distribution of solar modules, improve the collection of packaging for recycling and/or reduce the carbon footprint of consumer products by utilising primary packaging which comprises one or more solar modules. The main purpose is for the solar modules to be used in ways other than interacting with the primary package or the package contents directly.

At the same time advantageous use of the primary packaging material can be made by incorporating part of the primary packaging material in the solar cell.

According to a first aspect of the present invention, there is provided a primary packaging comprising an encapsulated volume or enclosure and a photovoltaic device having a transparent electrode, the photovoltaic device being provided on a surface of the encapsulated volume or enclosure with the transparent electrode facing towards the encapsulated volume or enclosure.

Preferably, the surface of the encapsulated volume or enclosure provided with the photovoltaic device is an interior surface.

Preferably, the surface of the encapsulated volume or enclosure provided with the photovoltaic device is an exterior surface.

It will be appreciated that reference to the exterior surface of the encapsulated volume or enclosure is a reference to a photovoltaic device being formed on or integrally within the outer surface of a material that provides a physical boundary of the internal volume or enclosure.

Preferably, the photovoltaic device is releasably provided on the surface of the encapsulated volume or enclosure.

Preferably, the photovoltaic device comprises a stack of layers including a substrate and/or a barrier layer and successive functional layers wherein the primary packaging incorporates the substrate and/or the barrier layer of the photovoltaic device.

Preferably, the primary packaging comprises a first barrier substrate having thereon the photovoltaic device having a photoactive charge-carriers generating layer being sandwiched between two conductive layers at least one of which is the transparent electrode.

Preferably, a second barrier substrate is positioned over an opposing layer of the photovoltaic device relative to the first barrier substrate.

Preferably, the encapsulated volume or enclosure comprises a flexible plastics material, a rigid plastics material, cardboard, paper, a foil or glass.

Preferably, the encapsulated volume or enclosure takes the form of a sachet, box, envelope or bottle.

Preferably, the transparent electrode is not exposed to light or is obscured to light whilst the primary packaging is performing its normal function as a first layer of packaging within which a product is contained.

Preferably, wherein the photovoltaic device does not provide any electrical power to a packaged product whilst the primary packaging is performing its normal function as a first layer of packaging within which the packaged product is contained.

Preferably, the photovoltaic device is a photovoltaic cell or comprises an array of photovoltaic cells forming a photovoltaic module. More preferably, the photovoltaic cell is a solar cell and the photovoltaic module is a solar module.

According to a second aspect of the present invention, a secondary packaging comprises primary packaging according to the first aspect of the present invention.

According to a third aspect of the present invention, an apparatus to collect and exploit the power generation capabilities of many such primary packaging entities comprises a framework support structure comprising a plurality of mountings for mounting an array of primary packaging modules each primary packaging module comprising a photovoltaic device; a first mounting for fixing a first primary packaging module to the framework support structure, a second mounting for fixing a second primary packaging module to the framework support structure and an electrical interconnect extending between the first and second mountings for electrically connecting first and second primary packaging modules together.

Preferably, the support structure comprises electrical output terminals for connection to an external load connectable across the array of primary packaging modules.

Preferably, an electronic monitoring unit is connectable to one or more primary packaging modules for providing power performance measurements on the one or more primary packaging modules and/or power output and charging characteristics for the load.

According to the third aspect of the present invention, the primary packaging has ceased to perform its normal function as a first layer of packaging within which a packaged product is contained and no longer provides an encapsulated volume or enclosure, the transparent electrode of the photovoltaic device as described in accordance with the first aspect of the present invention now being arranged to receive incident light.

In this way the packaging film is different to known packaging film where the solar cell may power the packaging in some way, such as to provide power to an animated image forming part of the advertising indicia.

When the primary packaging is no longer serving its function as a primary packaging then the photovoltaic device may provide electrical power to a load including any goods that may have been originally packaged within the primary packaging.

According to a fourth aspect of the present invention, the primary packaging is itself formed predominately or entirely from a photovoltaic device, therefore a primary packaging formed from a photovoltaic device provides an encapsulated volume or enclosure, a transparent electrode of the photovoltaic device facing towards the encapsulated volume or enclosure.

Preferably, the photovoltaic device comprises a first barrier substrate supporting a photoactive charge-carriers generating layer being sandwiched between two conductive layers at least one of which is the transparent electrode.

Preferably, a second barrier substrate is located over an opposing layer of the photovoltaic device relative to the first barrier substrate.

Preferably, the first barrier substrate is a stack including a flexible plastics material, a rigid plastics material, cardboard, paper, a foil or glass.

Preferably, the encapsulated volume or enclosure takes the form of a sachet, box, envelope or bottle.

Preferably, the transparent electrode is not exposed to light whilst the primary packaging is performing its normal function as a first layer of packaging within which a product is contained.

Preferably, the photovoltaic device does not provide any electrical power to a packaged product whilst the primary packaging is performing its normal function as a first layer of packaging within which the packaged product is contained.

Preferably, the photovoltaic device is a photovoltaic cell.

Preferably, the photovoltaic device comprises an array of photovoltaic cells forming a photovoltaic module.

Preferably, the photovoltaic cell is a solar cell and the photovoltaic module is a solar module.

According to a fifth aspect of the present invention, a photovoltaic cell may face away or towards the encapsulated volume or enclosure and be covered by, for example, a peelable label. Therefore, in a fifth aspect of the present invention, there is provided a primary packaging defining an encapsulated volume or enclosure and incorporating a photovoltaic device having a transparent electrode, the photovoltaic device being provided on a surface of the encapsulated volume or enclosure with the transparent electrode facing away from the encapsulated volume or enclosure, the primary packaging being provided with a removable label over an outer surface of the encapsulated volume or enclosure covering the transparent electrode.

According to a sixth aspect of the present invention there is provided a primary packaging defining an encapsulated volume or enclosure and incorporating a photovoltaic device having a transparent electrode, the photovoltaic device being provided on a surface of the encapsulated volume or enclosure with the transparent electrode facing towards the encapsulated volume or enclosure, the primary packaging being provided with a removable label over an outer surface of the encapsulated volume or enclosure covering the transparent electrode.

Preferably, the removable label is not transparent. Preferably, the removable label blocks 90% to 100% of light incident on the transparent electrode, 50% to 90% or 25% to 50%.

In a seventh aspect of the invention, the primary packaging is itself formed predominately or entirely from a photovoltaic device and without limitation to the orientation of the transparent electrode of the photovoltaic device. Therefore according the seventh aspect of the invention, the primary packaging is formed from a photovoltaic device providing an encapsulated internal volume or enclosure.

By combining high volume production techniques, PV integrated packaging meets an additional consumer need, providing access to power to those who need it. Furthermore individual packaging can be assembled into large arrays delivering more useful levels of electricity.

The addition of functionality of packaging after the package contents have been consumed acts as an incentive for the packaging to be collected, as opposed to being discarded. Once collected and assembled to larger entities, it is easier to find routes to recycle the packaging at end of functional life (e.g. after use as packaging and use as power source).

Additionally, by enabling the use of existing distribution channels through the addition of PV as a functional component of high volume, (and often relatively low value), consumer goods, a readily available and more established route to market for PV materials is accessed.

In an eighth aspect, not forming part of the present invention, the photovoltaic device may receive power whilst being part of the primary packaging in a module. According to an eighth aspect, not forming part of the present invention, there is provided a primary packaging defining an encapsulated volume or enclosure and incorporating a photovoltaic device having a transparent electrode, the photovoltaic device being provided on a surface of the encapsulated volume or enclosure with the transparent electrode facing away from the encapsulated volume or enclosure, the transparent electrode being exposed to incident light or the primary packaging being provided with a removable label over an outer surface of the encapsulated volume or enclosure covering the transparent electrode; wherein the primary packaging comprises an electrical connector for electrically connecting its photovoltaic device to additional primary packaging incorporating a photovoltaic device.

Preferably, two or more primary packages each define an encapsulated volume or enclosure and each primary package incorporates a photovoltaic device having a transparent electrode, the photovoltaic device on each primary package being provided on a surface of the encapsulated volume or enclosure with the transparent electrode facing away from the encapsulated volume or enclosure, the transparent electrode being exposed to incident light or provided with a removable label over an outer surface of the encapsulated volume or enclosure covering the transparent electrode; wherein the two or more primary packages are electrically connected together and to an external load.

### BRIEF DESCRIPTION OF THE DRAWINGS

The invention will now be described, by way of example only, with reference to the accompanying figures in which FIG. 1 shows an assembly of individual sub modules or cells to large modules

FIG. 2 shows packaging material combined with a solar cell. One barrier is provided by the packing material

FIG. 3 shows a packaging material comprising solar cell based on the metal wrap through solar cell architecture

FIG. 4 shows a packaging material comprising a solar cell. The metal film in the packaging material is serving as opaque electrode and barrier.

FIG. 5 shows a cross section of a primary packaging in accordance with a first aspect of the present invention comprising a solar cell. The light receiving (transparent) side of solar cell is facing the inside of the package

FIG. 6 shows a cross section of primary packaging in accordance with a further aspect of the present invention comprising a solar cell. The light receiving (transparent) side of solar cell is facing to the outside of the package

FIG. 7 shows an assembly of packed goods (photovoltaic packaging) (primary packaging and package contents) at point of sale for local power generation and assembly of packaging to large module by customer

FIG. 8 shows a Bottle with photovoltaic label (incl. cross section) in accordance with the present invention

FIG. 9 shows an assembly of photovoltaic bottles in accordance with the present invention to solar modules

FIG. 10 shows parallel interconnection of photovoltaic packaging modules in accordance with the present invention in an assembly frame

FIG. 11a shows a packaging material for use in primary packaging comprising elements of photovoltaic cells/modules

FIG. 11b shows a front (print) and back side (solar) of packaging material for use in primary packaging comprising matching patterns of printed front side and elements of photovoltaic cells/modules on the back side

FIG. 12 shows an assembly of photovoltaic modules based on photovoltaic—packaging material or—labels on a transparent carrier for use in primary packaging.

### DETAILED DESCRIPTION OF THE INVENTION

### Access to Electricity for the Poorest

By providing affordable photovoltaic cells or modules at the smallest useable size (and in some instances practically substantially below the smallest useful size for many useful consumer applications), consumers at the bottom of the pyramid can still access useful power by combining cells or modules, for instance enabling substantive charging of rechargeable batteries, either in a phone or similar device, or for powering associated lighting, refrigeration or other desirable electrically functional items. The fact that the consumer goods will come with additional secondary functionality may mean that a slight price premium is justified in the eyes of the consumer and the provision of a micro-PV cell will enable consumers to access what for them is a life changing capability.

An aspect of this invention is the subsequent connectorisation of the micro-PV system to provide useable power.

The provision of PV in what would ordinarily become waste packaging also provides a considerable inducement for collection, especially since it is highly likely that a number of these photovoltaic packaging products would need to be assembled together to provide enough energy to be particularly useful. This collection and connection into a larger source of power also means that at end of useful functional life, the material can be readily collected and recycled. Optionally a further inducement (material or financial) could be offered at a central collection point (e.g. at the premises of the original retailer) for returned cells or modules.

Structures for mounting the plurality of so collected waste materials also relate to the invention, as specific mountings will need to be developed, which could be one time use, or reusable.

The concept is illustrated in FIG. 1. Individual sheets of photovoltaic packaging material (01) are collected from otherwise discarded primary packaging. These will be collected on a carrier (02) which provides a mechanical component to keep the modules in respective places and a structure of electrical interconnection (03). Over the time, more photovoltaic packages are purchased together with the packaged product and mounted to the carrier. The power output increased accordingly. Different types of electronics with varying energy demand can be driven depending on the installed capacity (05). Depending on the ambient conditions and received light dose, the performance of the solar module will probably likely drop. In particular for low cost, low performance barrier materials, a half-life time (performance has dropped to 50% of initial performance) of months to years can be expected. The performance of the assembled solar module can be maintained by replacement of degraded sub-modules. Alternatively, fully assembled and degraded modules (05) can be brought back for recycling (06) and a new assembly of sub-modules onto a structure can be initiated.

An example calculation is given here to estimate the number of sub-modules that will be required for a certain output power under standard conditions (AM1.5 solar spectrum, 1000 W/m²). An exemplary sachet has the outer dimensions of 5 cm×8 cm. In a conservative assumption the photoactive area is 4 cm×6 cm or 24 cm². Calculations are done of 3%, 5% and 10% efficient cells. The individual sub-modules provide a power of 7.2, 12 and 24 mW respectively. This is in too little for substantive charging of batteries in current solar lighting units or mobile phones. The smallest solar powered lighting systems with sufficient light output for e.g. reading are equipped with solar modules of 100 mWp (LED torch). Current LED desk lamps require a 500 mWp solar module for daily operation. Direct mobile phone charging typically requires a minimum current of 500 mA at a voltage above 3.7V. Considering varying light conditions, a 2-3 Wp solar module is required.

In order to generate an output power of 500 mW, 70, 41 or 20 sub-modules are required with efficiencies of 3%, 5% or 10% respectively.

One potential beneficial result is that the delivery of the additional PV power results in an energy payback time (including cost of packaging, shipment and product contents) of less than the life of the solar cell/module, so that significant carbon savings can be achieved.

Both components, packaging and flexible organic photovoltaic are fabricated using the same or similar fabrication technologies. Common roll-to-roll processes are large area coating, lamination, printing (off-set, gravure, flexo, ink-jet), slicing and die cutting. An economic production of photovoltaic packaging can be therefore envisioned.

### The Photovoltaic Packaging or Label

The combination of packaging material with a photovoltaic cell or module results in an object with dual use, namely the protection of goods (whether packaged articles such as consumer electronics or transported goods such as liquids) during delivery until the point of consumption and secondly, the generation of electrical energy by conversion of sun-light to provide power to electrical consumers.

The main purpose of the solar module incorporated into the packaging material is not to provide power to any functional active components of the packaging. Also powering packaged goods, e.g. for extending their battery charge is not envisioned here. As a consequence the solar module is not connected to a load that would consume electrical power, which could provide an additional function for advertisement or powering of packaged goods.

The add-on value to the primary package of a transformer of solar energy to electrical energy incentivises collection of the primary packaging materials and will allow implementing mechanisms of waste reduction. Depending on the implementation the power can be extracted during the life cycle of the primary packaging material at any point in time or after the opening of the primary package.

The use of similar or even the same materials in the form of thin films (in the order of several tens to 100 micrometres) for primary packaging and for thin film solar makes the combination of the two very attractive. The similarity of the materials results in a compatibility of a wide range of processes established for packaging materials and under development for thin film solar cells and modules, in particular plastic solar cells. Exemplary processes relevant for both components are wet film coating, printing, vacuum metallization and lamination. Increasing the level of integration of the two functionalities (packaging and electricity generation) would allow reduced costs to be achieved for combined object, as compared to the two individually. This can be achieved by the dual use of components, like a common barrier for packaged goods and for protection of the solar cell, but also by efficient use of the production equipment. The similarity in the types of materials used for fabrication (carbon based and metals) would enable the use of identical recycling processes. Additional recycling process steps might be required for consideration of the complete device stack.

Primary packaging material comprising photovoltaic cells or modules is preferably fabricated by roll-to-roll processes.

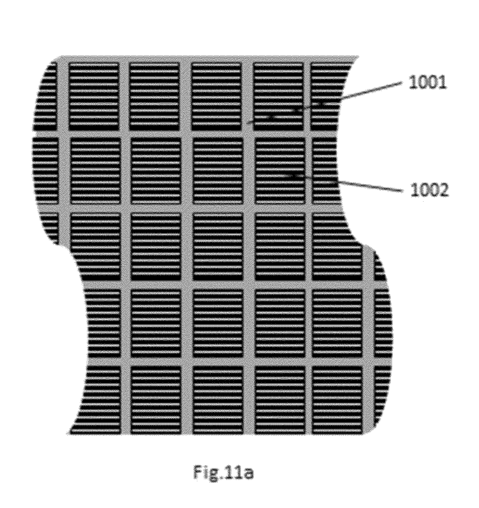

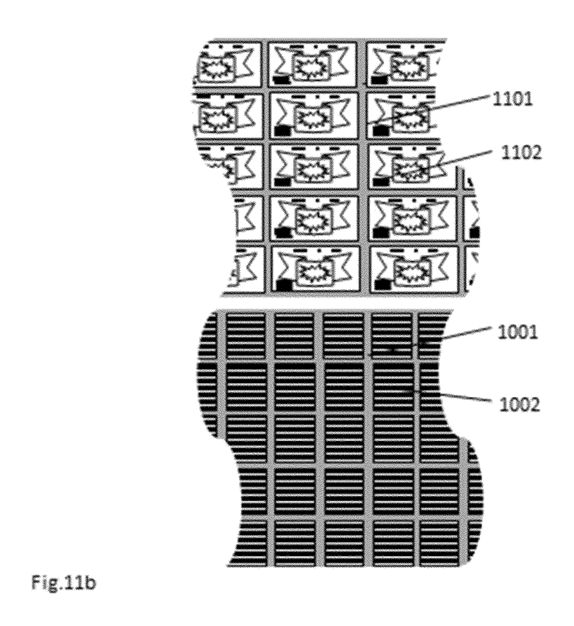

For the later assembly of packaging material based solar cells and modules into primary packaging, the dimensions, output voltage (of individual cells or modules with incorporated series interconnection) and points or areas for electrical interconnection have to be defined. This can be done by predefined areas of the solar cell or module elements or by cutting a predominately un-structured photovoltaic packaging film to size. An example is presented in FIG. 11a where a packaging material (1001) with defined cell or module elements (1002) is shown. The defined elements can be cells (with sufficiently conductive transparent electrode for efficient charge carrier extraction) or modules. These modules can be still interconnected (parallel and/or serial) by metal layers. The separation of the photovoltaic packaging materials will be done along the borders of individual or multiple pre-defined cell or module elements. In large scale roll to roll production the packaging film as shown in FIG. 11 a will contain multiple segments with repetitive prints (1101) (which depict product information, logos, pictures, etc.) on the front side (1102) which will be separated later for individual packages or labels. A packaging film combined with solar cells or modules will contain multiple printed segments on the front side and multiple segmented solar cells or modules (1002) on the back side, characterized in that one or more functional solar cells or module segments are located within the area of the printed segment on the front side. The separation of the film (die-cutting) prior to the formation of packages or labels will result in one or multiple solar cells or modules on the back-side. Thickness of the solar cells or modules containing packaging film will be less than one millimetre, likely less than 500 micrometres.

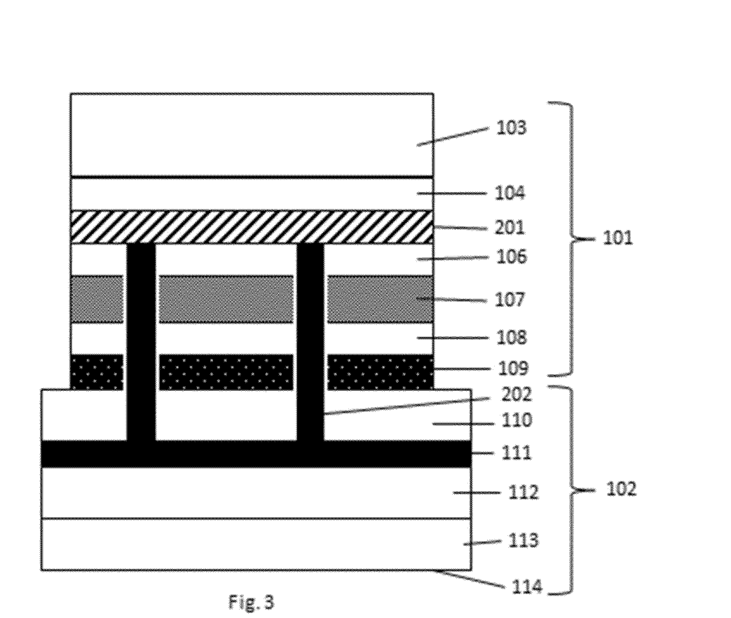

In contrast the separation and connectorisation of un-structured photovoltaic packaging film requires a cell/module architecture that sustains cutting (die-cutting) without the creation of electrical shunts between the electrodes. A suitable cell architecture is based on the contact wrap through concept described below and shown in FIG. 3. The highly conductive electrodes are separated by a relatively thick dielectric layer in contrast to an only several tens to hundreds of nanometres thick photoactive layer.

Variants of a packaging material combined with thin film solar cells and/or modules to create primary packaging are discussed below.

### FIG. 1 Packaging Comprising a Solar Cell

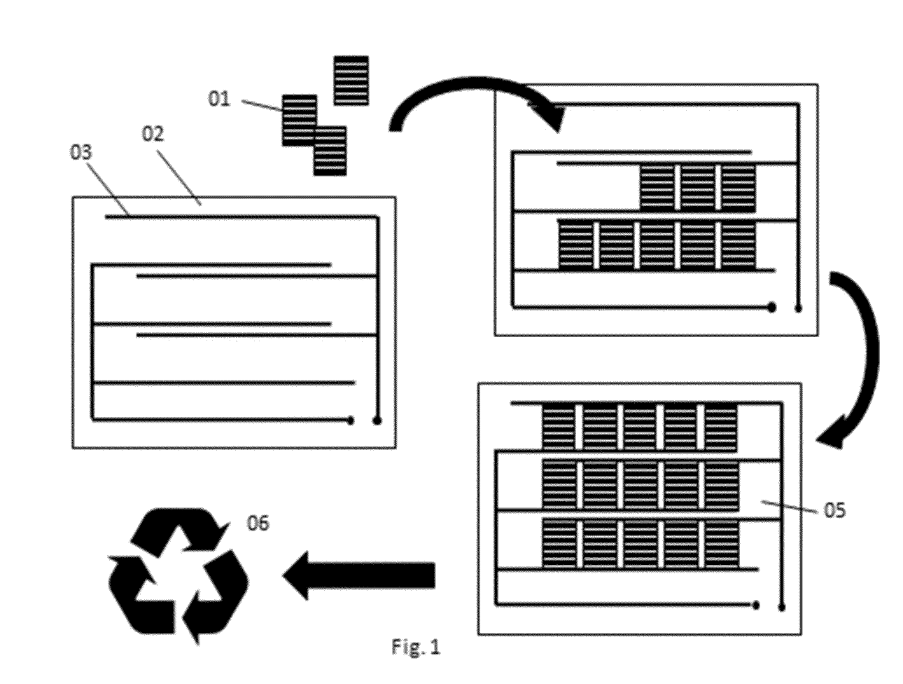

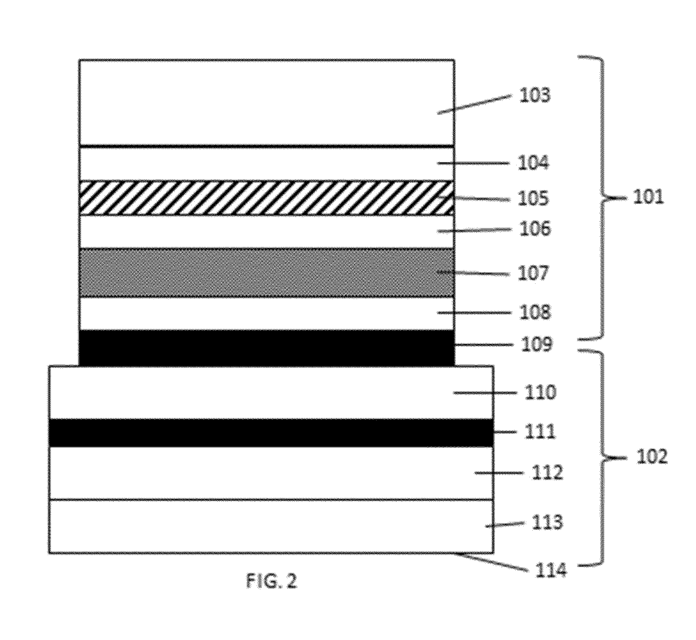

FIG. 2 shows an example of the invention incorporating a typical multi-layer stack consisting of two primary functional components—a packaging material (102) and a thin film solar cell or module (101). The packaging material provides protection for packaged goods during transportation and at the same time serves as a protective barrier for the solar cell.

The packaging material is built up on a plastic film (112) (PET, PE, etc.) optionally with a paper or subbing layer (113) on the outside. The outside is defined here as the outside of the primary package in later use. The branding is applied for instance by printing on the outermost side of the primary packaging, called a print (114). A metal film (111) providing enhanced barrier properties is deposited on the inside (facing towards the packaged product) of the PET film (112). A sealing medium (110) is deposited on top of the metal film.

The configuration of the solar cell or module is described here starting from the superstrate film (103). (The covering on the illuminated side of a photovoltaic (PV) module, providing protection for the PV materials from impact and environmental degradation while allowing maximum transmission of the appropriate wavelengths of the solar spectrum.) The superstrate film 103 comprises the covering on the illuminated side of a photovoltaic (PV) module, providing protection for the PV materials from impact and environmental degradation while allowing maximum transmission of the appropriate wavelengths of the solar spectrum and preferably comprises a PET film.). This can be coated by a transparent barrier (104), which can also be laminated as a separate film to the opposite side of the superstrate (103). The transparent barrier is covered by a transparent electrode (105). The transparent electrode can be a single, highly doped layer (e.g. Indium doped tin oxide (ITO)), a layer sandwich of metals and metal oxides or a metal grid with a conductive field filler (e.g. PEDOT:PSS). The subsequent layer is an interface layer (106) facilitating the efficient extraction of charge carriers. This layer is followed by the photoactive layer (107) and in some cases by an interface layer (108) for the extraction of the opposite charge carrier. An opaque electrode (109) is deposited on top of the interface layer.

The two components, thin film solar cell/module (101) and packaging material (102) can be fabricated separately and joined in a subsequent lamination process to manufacture the primary packaging.

### Packaging Comprising Solar Cell—Wrap Through Concept

The example of a packaging material comprising a solar cell is based on the known concept of a contact wrap through solar cell architecture (FIG. 3). The difference from the above described architecture is that the transparent electrode (201) in this case only requires a lower conductivity as the current is extracted by wrap through interconnects (202) from smaller cell areas. The interconnects make electrical contact to the metal film (111) provided by the packaging material. A crucial element for the implementation of this architecture is the electrical isolation of the interconnects from the opaque electrode (109) of the solar module.

### Packaging Comprising Solar Cell—Metal Film in Packaging Serving as Opaque Electrode and Barrier

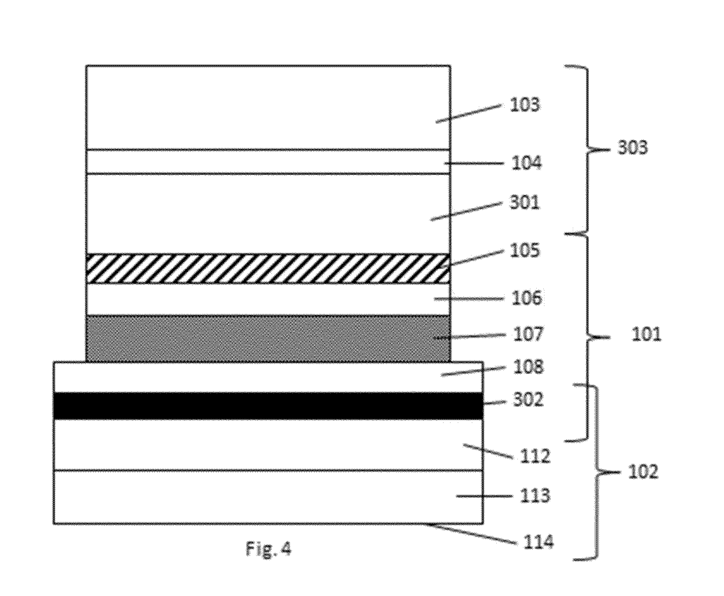

FIG. 4 depicts another example of primary packaging comprising a solar cell (101) which is based on a solar cell built up on a packaging substrate (102) (FIG. 4). The metal layer (302) serves as electrode and barrier simultaneously. (In this configuration, the individual solar unit is not separated in monolithically interconnected elements to provide a higher operating voltage. Instead, solar units of individual packages need to be connected in series externally to provide higher voltages.) The metal layer may require an additional interface layer (108). Subsequently deposited layers are the photoactive layer (107), an interface layer (106) for the opposite charge carrier and a transparent electrode layer or grid structure including a conducting field filler (105). An encapsulation (303) using adhesive (301) is laminated on top. Alternatively this encapsulation can be done in form of a coating.

The primary packaging may be constructed such that the transparent electrode layer is directed towards the inside of the primary packaging created or is directed outwards. If it is directed outwards further packaging material (not shown) may be provided to overlie the transparent electrode. This further packaging material is removeable and non-transparent. The further packaging material need not be wholly opaque, blocking 100% of the incident light, but block a lesser percentage eg 90%, 80% down to around 25%. Preferably, the further packaging material takes the form of a peelable label that may be removed when the primary packaging is to be used as a PV power source.

### Packaging Comprising Solar Cell—Transparent Side of Solar Cell is Facing the Inside of the Package

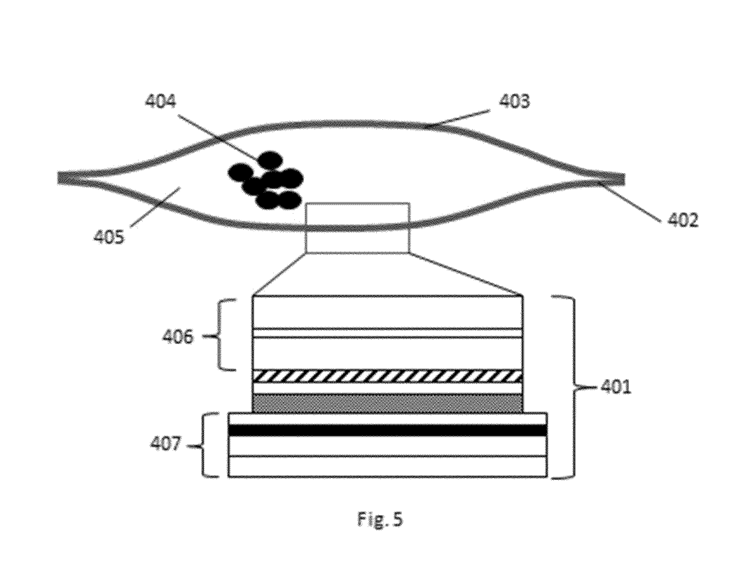

FIG. 5 depicts a cross section of an example where packaging material comprising a solar cell (401) is used to form a primary package (403) for goods or packaged products (404) by lamination at the edges to form a sealed compartment (402) (cross section is shown in FIG. 5). The transparent side (406) of the solar cell is facing the inside of the package, the opaque side is facing the outside of the packaging. In other words, it can be seen that the primary packaging (403) comprises an encapsulated volume or enclosure (402) for enclosing packaged goods as well as a solar cell having a transparent electrode (406), the solar cell being provided on a surface of the encapsulated volume or enclosure with the transparent electrode (406) facing towards the encapsulated volume or enclosure.

Semi-transparent packaging material with two transparent barriers and two transparent electrodes is also envisioned. The packaging can be done under defined conditions, providing for example an inert gas (405) condition. The packaging under inert conditions would allow extending the shelf life time of the packaged solar cell.

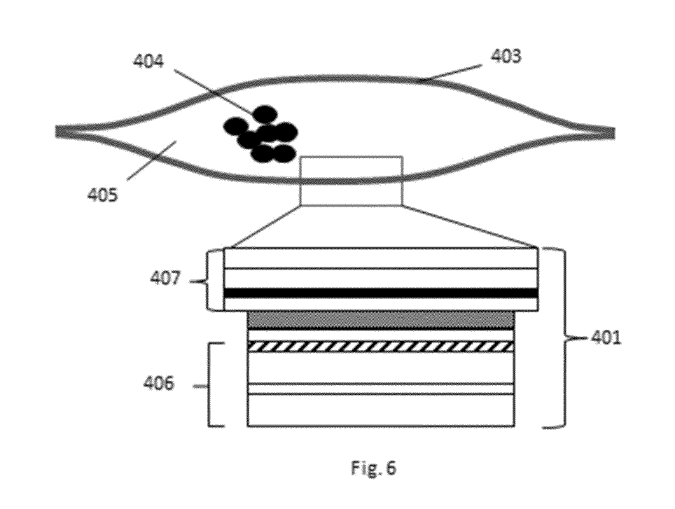

A configuration with the light receiving side of the solar cell facing outwards is shown in FIG. 6. In such an example further packaging material (not shown) may be provided to overlie the transparent electrode (406). This further packaging material may be removeable. Preferably the further packaging material is non-transparent. The further packaging material need not be wholly opaque, blocking 100% of the incident light, but block a lesser percentage eg 90%, 80% down to around 25%. Preferably, the further packaging material takes the form of a peelable label that may be removed when the primary packaging is to be used as a PV power source.

Labels with Integrated Solar Modules (e.g. for PET Bottles)

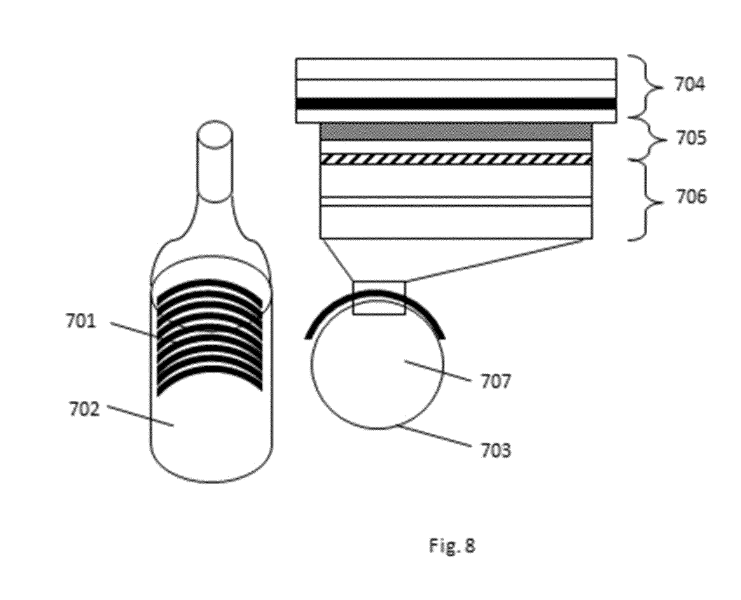

FIG. 8 shows the concept of a photovoltaic label/package (701) as an integral component of a bottle (702). The sun light receiving side of the solar module (706) is facing towards the inside of the bottle. The backside of the module carries the product information on the label (704). In this configuration, the PET material of the bottle will at least partially provide a barrier property for the solar module/cell (705). The label can be either an integral part of the solar cell/module and provide the functionality of a barrier and an electrode or can provide only one of the functionalities. In order to further improve the protection of the solar module against moisture and or Oxygen, water (e.g. quicklime (CaO)) and or Oxygen scavengers (707) can be put into the bottle in order to reduce the partial pressure of the respective gas.

Alternatively the primary packaging, that is the labelled bottle can also have an opaque or tinted packaging material that would not allow a sufficient amount of light to pass through the packaging to generate electricity for relevant applications. In a preferred embodiment the label comprising a solar cell or module on its back side can be removed from the package without damage for separate use as a solar module and assembly to larger modules. The use of such a removeable solar cell or module means that the primary packaging can be of any suitable material, including glass or plastics.

It will be understood that notwithstanding the opening at the neck of the bottle, during transport of the packaged goods, the bottle as primary packaging provides an encapsulated volume or enclosure sealed with a cap.

In an alternative embodiment, not shown, the label may be provided on the external surface of the packaging, but with the transparent electrode of the solar cell instead facing away from the packaging. In this embodiment, further packaging material in the form of a peelable label can be provided to overlay the transparent electrode of the solar cell.

### Assembly of Packaging Based Solar Cells

Although the general concept of interconnection of photovoltaic sub-units to modules or modules to photovoltaic installations (roof mounted) or to photovoltaic power plants is known, the proposed concept of primary packaging combined with photovoltaic units has unique aspects. The individual photovoltaic units provided by such primary packages do not supply sufficient power for the majority of applications. Exemplar applications are lighting or mobile phone charging. Nevertheless, the limitation to small sizes makes the solar modules affordable and implementable into packaging. Different application scenarios with regard to the assembly are possible. Where the module is facing outwards, the assembly of individual units to modules to provide higher power output could in some instances be done while the products are still packaged. In this case the individual module has to be exposed to the light by at least partly removing the additional packaging material (e.g. a label), thus revealing the solar module. The application would be to provide power for various applications by connecting the individual packages into blocks to be connected to a load or battery at the point of sale or even before. Examples are powering of the light of a market stand, charging batteries or charging mobile phones. After unpacking of the packaged product, the consumer can use the primary package for its second purpose, the generation of electricity. This requires assembly of numerous individual solar packages to larger modules with increased power output. Depending on the methodology for electrical and mechanical interconnection this can be done by the consumer directly or can be offered as a service.

Depending on the type of primary packaging, various concepts for module/cell assembly can be envisioned.

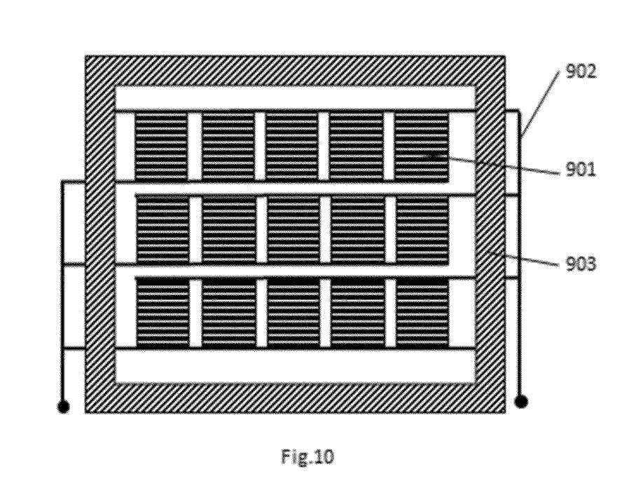

For the assembly of primary packaging material based flexible solar modules/cell to larger systems with higher power output, a mechanical structure and a means for electrical connectorisation is required. Numerous concepts can be envisioned and the best solution for a given application depends, amongst other aspects, on the mechanical properties of the packaging, the scale of the assembled system, the locally available resources and labour as well as the users acceptance. FIG. 10 depicts a collection of mini-modules mounted on a frame (903) and comprising wires (or other means of electrical connection) (902). Where a shorter life-time of low cost packaging based solar modules is envisaged (on the order of months to several years for instance), in contrast to several tens of years (for inorganic photovoltaic modules), a separation between single and short term use of disposable components (the solar modules, 901) and durable, and in most cases more energy containing components like electrical wires (902) and mechanical structures (903), is favourable from an economic and environmental perspective (FIG. 10). The need for frequent mounting and removal has to be considered in the design of such structures. The scale of these structures can vary from small areas of several tens of square centimetres to solar fields with the size of square kilometres.

Assemblies with Packaging Providing Structural Properties

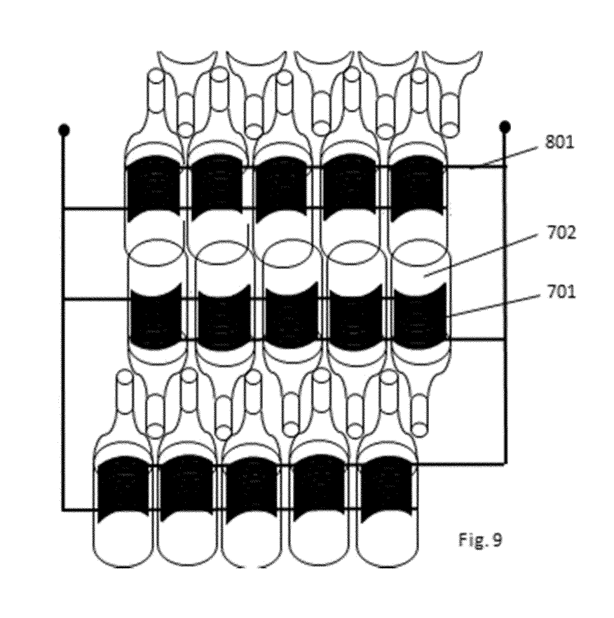

Direct interconnection of primary packaging based modules without additional structural elements can be envisioned for flexible thin film packaging and also for cardboard packaging or bottles. An example for the assembly of bottles containing a photovoltaic label is shown in FIG. 9. The bottle (702) has an affixed PV module (701), and several bottles are arranged to work in series and/or parallel by electrical connecting medium (801) such as wires.

Mechanical interconnection of photovoltaic packaging units can be done by adhesives (e.g. pressure sensitive adhesive), rivets, sewing, welding, ultrasonic welding. The electrical interconnection can be provided by mechanical pressure between the contacts provided by the mechanical interconnect, by silver paste, soldering or conductive adhesives. Crimp contacts can provide the mechanical and electrical connection at the same time.

In the case of cardboard packaging, the primary packaging may take the form of a cardboard envelope or box. It will be appreciate that although an encapsulated volume or enclosure will be formed, such that the primary packaging forms an enclosed volume for the packaged product, the enclosure need not be airtight. In a preferred example of an embodiment of the present invention, the primary packaging may further be provided with small openings to serve as ventilation openings—for example in the provision of a cardboard box for the transport of fruit.

### Glass as Supportive Structure

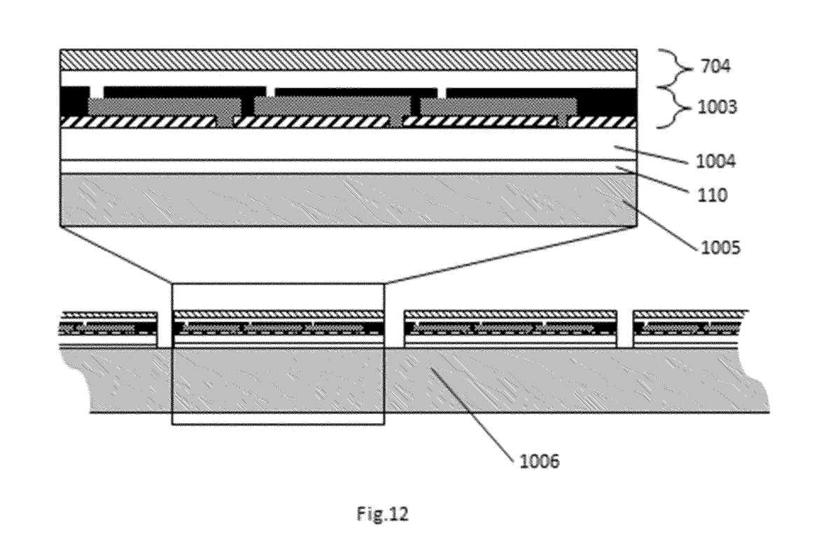

Glass plates can be utilized as supportive structures for assemblies of packaging based solar modules. In addition to the mechanical rigidity, the glass plate provides excellent additional barrier properties. Electrical interconnection of individual units can be done by overlapping if the electrical contact area or additional conductive stripes or adhesives. An example of such a structure is shown in FIG. 12. The solar module 1003 is protected by the barrier provided by the packaging material 704. The substrate 1004 provides limited barrier properties for the solar module. The module elements are laminated to the transparent substrate (preferably glass or transparent alternatives with suitable barrier properties) using an adhesive 110. In case of a poor barrier property of layer 1004, oxygen and moisture will have diffused into the functional layers of the solar module before mounting onto the glass carrier. In such cases an additional oxygen and or moisture scavenger is preferably incorporated into the sandwich, for example into the transparent adhesive. The electrical interconnection of the photovoltaic elements is not shown in FIG. 12. The lamination of solar modules to glass is known. Novel is the lamination of packaging materials comprising solar cells/modules as individual units to a common substrate providing mechanical and chemical protection and electrically connecting these units.

### Disposable Supportive Structures

The mechanical assembly and electrical interconnection of individual primary packaging units can be done by employing a mechanical support structure. Preferably this mechanical support structure is a low cost structure built up on materials that can go through the same recycling process (e.g. pyrolysis) as the assembled solar modules. The support structure can also be used to incentivise the customer to bring the assembled system back for recycling when the solar modules are degraded. A new support structure can be handed out in exchange of the assembled and degraded system. Closing of the recycling loop is required in order to solve the waste problem. The support structure can be made of glass, PET, PE, cardboard and/or paper. In addition to the mechanical support, the structure can carry an adhesive layer (peelable) film for mounting of the solar packaging material. Another component can be structures providing the electrical interconnect for the modules. This interconnect can consist of thin metal wires or ribbons printed metal tracks or structured thin metal films. The electrical contact between conductive lines on the support structure and the contacts of the solar modules can be made by conductive adhesives, rivets, crimps, etc.

The support structure can provide additional information/instructions on the mounting of solar packaging material. Information on the appropriate mounting, polarity, position and expected power output for specific applications can be given.

The support structure can also contain active elements, like electronics that provide information on the performance of individual solar cells or the complete assembly (end-of life test). Information on power output and/or voltage and/or current or a descriptive indicator for power levels achieved for charging/powering specific components.

The support structure can also provide mechanical and electrical contact structures for rechargeable batteries. Alternatively the batteries are already integrated in the mechanical support structure including the charging electronics.

Further optional electronic components for integration in the support structure are lights, light emitting diodes, organic light emitting diodes, LCD displays & radio circuitry.

### Assembly of Packaging at Point of Sale for Local Use

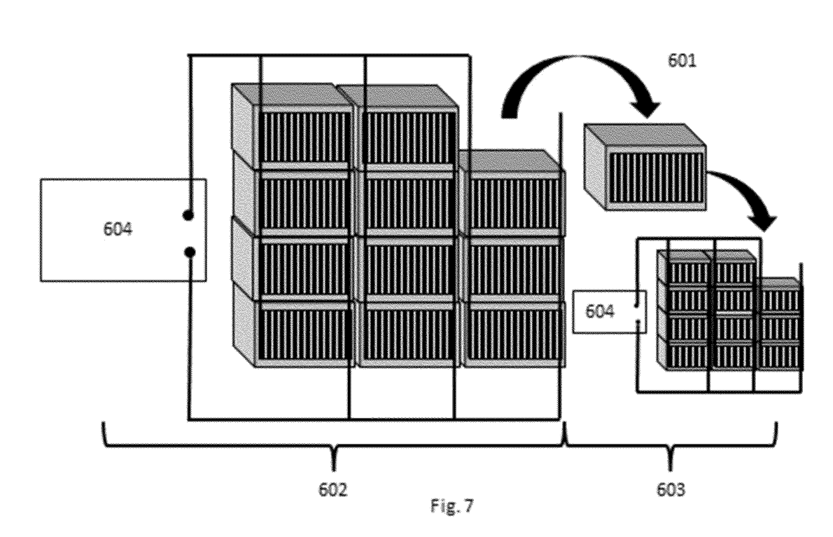

In one configuration the primary packaging contains a photovoltaic cell or module (601) (FIG. 7). The photovoltaic component can be either laminated to the packaging material, forming a unit or can be functional part of the primary packaging material. Once revealed, the photovoltaic unit allows easy access to the electrical contacts for interconnection of individual solar units. This interconnection can be done at the point of sale (602). In this case the assembled units can provide power for electrical consumers, e.g. light or mobile phone charging (604). Primary packages containing the solar module can be assembled by the customer (603) for the same purposes.

### Assembly of “PV Bottles” to Solar Modules

FIG. 9 shows the assembly of “photovoltaic” bottles to solar modules of higher output power. Here, a parallel interconnection of the individual modules is shown. A series interconnection is required if higher voltages are needed.

### Parallel Interconnection of Photovoltaic Packaging Modules (in Contrast to Cells)

FIG. 10 shows an example for interconnection of solar packaging elements to pv-modules (901) with higher power output. The solar packaging modules shown here provide sufficiently high voltages for the envisioned applications (e.g. battery charging). The modules are interconnected in parallel to increase the electrical current. The interconnection is done by metal wires (902) stretched in a frame (903). The modules are connected with their respective electrical contacts to the wires. This can be done by clamps, conductive adhesives, etc.

1: Primary packaging comprising an encapsulated volume or enclosure and a photovoltaic device having a transparent electrode, the photovoltaic device being provided on a surface of the encapsulated volume or enclosure with the transparent electrode facing towards the encapsulated volume or enclosure.

2: Primary packaging according to claim 1, in which the surface of the encapsulated volume or enclosure provided with the photovoltaic device is an interior surface.

3: Primary packaging according to claim 1, in which the surface of the encapsulated volume or enclosure provided with the photovoltaic device is an exterior surface.

4: Primary packaging according to claim 1, in which the photovoltaic device is releasably provided on the surface of the encapsulated volume or enclosure.

5: Primary packaging according to claim 1, in which the photovoltaic device comprises a stack of layers including a substrate and/or a barrier layer and successive functional layers wherein the primary packaging incorporates the substrate and/or the barrier layer of the photovoltaic device.

6: Primary packaging according to claim 1, wherein the primary packaging comprises a first barrier substrate having thereon the photovoltaic device having a photoactive charge-carriers generating layer being sandwiched between two conductive layers at least one of which is the transparent electrode.

7: Primary packaging according to claim 6, including a second barrier substrate over an opposing layer of the photovoltaic device relative to the first barrier substrate.

8: Primary packaging according to claim 1, in which the encapsulated volume or enclosure comprises a flexible plastics material, a rigid plastics material, cardboard, paper, a foil or glass.

9: Primary packaging according to claim 1, in which the encapsulated volume or enclosure takes the form of a sachet, box, envelope or bottle.

10: Primary packaging according to claim 1, in which the transparent electrode is not exposed to light or is obscured to light whilst the primary packaging is performing its normal function as a first layer of packaging within which a product is contained.

11: Primary packaging according to claim 1, wherein the photovoltaic device does not provide any electrical power to a packaged product whilst the primary packaging is performing its normal function as a first layer of packaging within which the packaged product is contained.

12: Primary packaging according to claim 1, wherein the photovoltaic device is a photovoltaic cell.

13: Primary packaging according to claim 1, wherein the photovoltaic device comprises an array of photovoltaic cells forming a photovoltaic module.

14: Primary packaging according to claim 12, wherein the photovoltaic cell is a solar cell and the photovoltaic module is a solar module.

15: Secondary packaging comprising primary packaging according to claim 1.

16: A framework support structure comprising a plurality of mountings for mounting an array of primary packaging modules each primary packaging module comprising a photovoltaic device; a first mounting for fixing a first primary packaging module to the framework support structure, a second mounting for fixing a second primary packaging module to the framework support structure and an electrical interconnect extending between the first and second mountings for electrically connecting first and second primary packaging modules together.

17: A framework support structure as claimed in claim 16, wherein the support structure comprises electrical output terminals for connection to an external load connectable across the array of primary packaging modules.

18: A framework support structure as claimed in claim 16 comprising an electronic monitoring unit connectable to one or more primary packaging modules for providing power performance measurements on the one or more primary packaging modules and/or power output and charging characteristics for the load.

19: A framework support structure as claimed in claim 16, including an array of mounted primary packaging as claimed in any preceding claim, wherein the primary packaging has ceased to perform its normal function as a first layer of packaging within which the packaged product is contained and no longer provides an encapsulated volume or enclosure, the transparent electrode of the photovoltaic device being arranged to receive incident light.

20: Primary packaging according to claim 13, wherein the photovoltaic cell is a solar cell and the photovoltaic module is a solar module.
